(19) United States
(12) Patent Application Publication
(10) Pub. No.: US 2006/0049475 A1
(43) Pub. Date: Mar. 9, 2006

(54) High power LED array

(75) Inventors: Hung-Tung Wang, Hsinchu City (TW); Chien-Chen Hung, Hsinchu City (TW); Shun-Lih Tu, Taipei City (TW); Dennis Chih-Yuan Yen, Hsinchu City (TW); Chih-Hung Chuang, Hsinchu City (TW); Huai-Ku Chung, Hsinchu City (TW); Cheng-Wei Yang, Chilung City (TW); Tsu-An Han, Kaohsiung Hsien (TW)

Correspondence Address: BIRCH STEWART KOLASCH & BIRCH, PO BOX 747, FALLS CHURCH, VA, 22040-0747, US

(73) Assignee: OPTO TECH CORPORATION

(21) Appl. No.: 11/073,701

(22) Filed: Mar. 8, 2005

(30) Foreign Application Priority Data
Sep. 7, 2004 (TW) 93127017

(51) Int. Cl. H01L 31/0232

(52) U.S. Cl. 257/432

(57) ABSTRACT

The present invention relates to a high-power LED array. The high-power LED array has a printed circuit board (PCB), anodes, cathodes, high-power LED dies, packing materials, and lenses. The PCB has cavities arranged in an array. One anode and one cathode are located in each cavity. The anode and the cathode are correspondingly connected to the anode and cathode in the neighboring cavities. At least one high-power LED die is placed in the cavity and connected to the anode and the cathode in series or in parallel. The cavity is filled with packing material to secure the high-power LED die. Lenses are placed on the cavities to focus light emitted by the high-power LED die.

### RELATED APPLICATIONS

The present application is based on, and claims priority from, Taiwan Application Serial Number 93127017, filed Sep. 7, 2004, the disclosure of which is hereby incorporated by reference herein in its entirety.

### BACKGROUND

1. Field of Invention

The present invention relates a high-power Light Emitting Diode (LED). More particularly, the present invention relates to a high-power LED array.

2. Description of Related Art

A high-power LED array, such as a III-V high-power LED array, is frequently employed in outdoor display panels. Conventionally, packed high-power LEDs are assembled on a Printed Circuit Board (PCB) to form this type of high-power LED array. FIG. 1 is a diagram illustrating the conventional high-power LED array. The high-power LED 100 includes an anode 101, a cathode 102, a high-power LED die 103, and a lens 104. The packed high-power LED 100 is connected to a PCB 110.

The high-power LED die 103 is placed in a cavity 106 of the cathode 102. The high-power LED die 103 is electrically connected to the cathode 102. The high-power LED die 103 is also electrically connected to the anode 101 via a wire 105. The cavity 106 is then filled with packing material to secure the high-power LED die 103 in the cavity 106. The packing material is also used as electrical isolation between the anode 101 and the cathode 102. The lens 104 is placed on the anode 101 to focus light emitted by the high-power LED die 103. After high-power LEDs 100 are all electrically connected to the PCB 110, anodes 101 of the high-power LED 100 are electrically connected by anode wires 107.

However, several drawbacks arise for the conventional high-power LED array. First, when the high-power LED array is manufactured by assembling packed LEDs, the size of the LED array is usually bulky. Additional assembling procedures are required, and the manufacturing cost is therefore increased.

Besides, optical misalignment is another issue concerned for the conventional high-power LED array. The optical misalignment results from the misalignment of the packed LED during the assembling procedures. The optical misalignment results in divergence and decreased light intensity. Since the lens inside the packed LED can't be adjusted, an additional external lens is usually required for re-focusing light emitted from the high-power LED array.

Furthermore, inefficiency of heat dissipation is another disadvantage. Since the packed LED has a smaller surface area, the dissipation efficiency is compromised. The inefficiency of heat dissipation further degrades the light intensity of the high-power LED array.

### SUMMARY

It is therefore an objective of the present invention to provide a high-power LED array with decreased size, efficient heat dissipation, and improved optical alignment.

It is another objective of the present invention to provide a high-power LED array packing method for packing a high-power LED array on a PCB.

In accordance with the foregoing and other objectives of the present invention, a high-power LED array is provided. The high-power LED array includes a PCB, anodes, cathodes, high-power LED dies, packing material, and lenses. The PCB includes cavities arranged in an array. The cavity contains an anode and a cathode. The anodes are electrically connected. The cathodes are also electrically connected. At least one high-power LED die is located in the cavity. The high-power LED die is electrically connected to the anode and the cathode of the cavity in series or in parallel. The cavity is filled with packing material for securing the high-power LED die. A lens is placed on the cavity for focusing light emitted by the high-power LED die.

According to another objective of the present invention, a high-power LED array packing method for packing a high-power LED array on a PCB is provided. The PCB includes cavities arranged in an array. The cavity contains an anode and a cathode. The anodes of the cavities are electrically connected. The cathodes of the cavities are also electrically connected. According to the high-power LED packing method of the present invention, at least one high-power LED die is first placed in the cavity. Next, the high-power LED die is electrically connected to the anode and the cathode of the cavity in series or in parallel. Further, the cavity is filled with packing material for securing the high-power LED die in the cavity. Finally, a lens is placed on the cavity to focus light emitted by the high-power LED die. The placement of the high-power LED die can be adjusted to optimize the light output.

The high-power LED array according to the present invention has a significantly reduced size, and the efficiency of heat dissipation and the optical alignment are also improved. The placement of the lens on the cavity can be adjusted to optimize the light output. Further, the configuration of more than one high-power LED dies in the cavity enables the combination of high-power LED dies with different emission wavelengths in a single high-power LED array. The light intensity per unit area of the high-power LED array is also dramatically increased. Further, the high-power LED array packing method according to the present invention simplifies the packing procedures, increases the power-to-volume ratio, and reduces the manufacturing cost.

It is to be understood that both the foregoing general description and the following detailed description are examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a cross-sectional diagram illustrating the conventional high-power LED array;

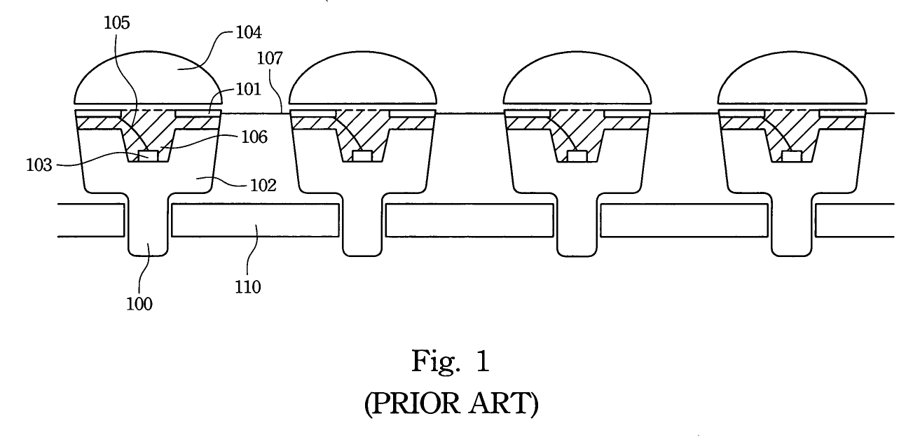

FIG. 2 is a cross-sectional diagram illustrating the high-power LED array according to the first preferred embodiment of the present invention;

FIG. 3 is a cross-sectional diagram illustrating the high-power LED array according to the second preferred embodiment of the present invention;

FIG. 4 is a cross-sectional diagram illustrating the high-power LED array according to the third preferred embodiment of the present invention;

FIG. 5 is a cross-sectional diagram illustrating the high-power LED array according to the fourth preferred embodiment of the present invention;

FIG. 6 is a cross-sectional diagram illustrating the high-power LED array connecting to a secondary heat sink according to the present invention; and

FIG. 7 is a flowchart illustrating the high-power LED array packing method according to the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

According to the high-power LED array of the present invention, the high-power LED dies are directly packed in the cavities of the PCB. The size of the high-power LED array can therefore be reduced dramatically. Further, the heat sink in the PCB also improves the efficiency of heat dissipation. Additionally, the placement of the lens on each cavity can be adjusted to optimize light output from the high-power LED array.

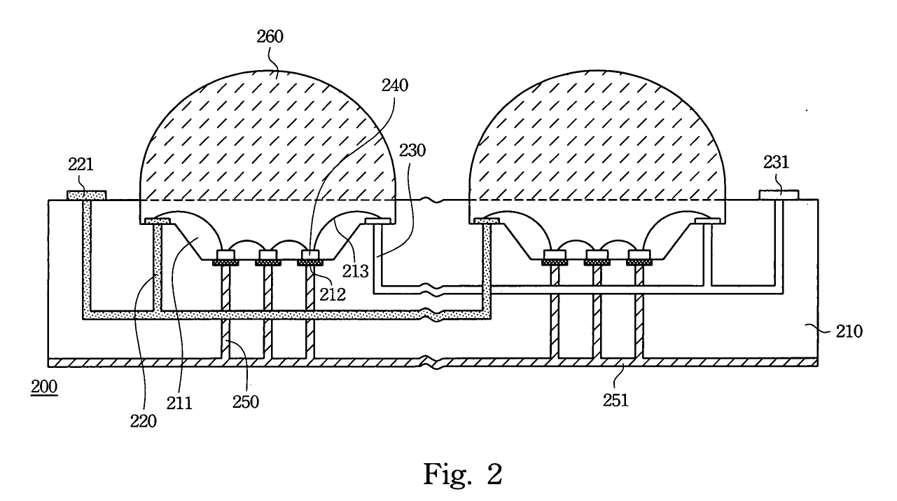

FIG. 2 is a cross-sectional diagram illustrating the high-power LED array according to the first preferred embodiment of the present invention. The high-power LED array 200 according to the first preferred embodiment of the present invention includes a PCB 210, anodes 220, cathodes 230, high-power LED dies 240, heat sinks 250, and lenses 260.

The PCB 210 includes cavities 211 arranged in an array. One or more high-power LED dies 240 are placed in the cavity 211. More than one high-power LED dies 240 with the same emission wavelength, such as blue color high-power LED dies, can be placed in the cavity 211. Alternatively, a combination of high-power LED dies 240 with different emission wavelength can be employed. For example, a combination of red, green, and blue color high-power LED dies 240 in the cavity 211 results in a white, high-power LED array.

An anode 220 and a cathode 230 are inside the cavity 211, and are electrically connected to the high-power LED dies 240 for providing power to the high-power LED dies 240. The anode 220 and the cathode 230 of the cavity 211 are correspondingly connected in parallel to the anode 220 and the cathode 230 of the adjacent cavity 211. The anode 220 and the cathode 230 are further connected to a common anode 221 and a common cathode 231, respectively.

The high-power LED dies 240 inside the cavity 211 are connected in series. As shown in the FIG. 2, the high-power LED dies 240 are placed on metal contacts 212 in the cavity 211. All high-power LED dies 240 are electrically connected via the wire 213, and are further connected to the anode 220 and the cathode 230 in the cavity 211.

Further, the PCB 210 includes heat sinks 250. The heat sink 250 corresponds to each high-power LED die 240, and is located underneath the metal contact 212. The heat sink 250 is connected to the metal contacts 212 for conducting the heat generated by the high-power LED dies 240. The heat sink 250 is further connected to a common heat sink 251. The common heat sink 251 is located on the backside of the PCB 210 for providing larger dissipation area. The heat generated by the high-power LED dies 240 can be dissipated efficiently by the common heat sink 251.

After the high-power LED dies 240 are placed in the cavity 211 and electrically connected to the anode 220 and the cathode 230 via the wire 213, he cavity 211 is filled with packing material for securing the high-power LED dies 240. The packing material can be silicone or epoxy.

Subsequently, the lens 260 is placed on the cavity 211 and bonded to the packing material. The placement of the lens 260 can be adjusted for respective cavity 211 to optimize light emitted from each cavity 211.

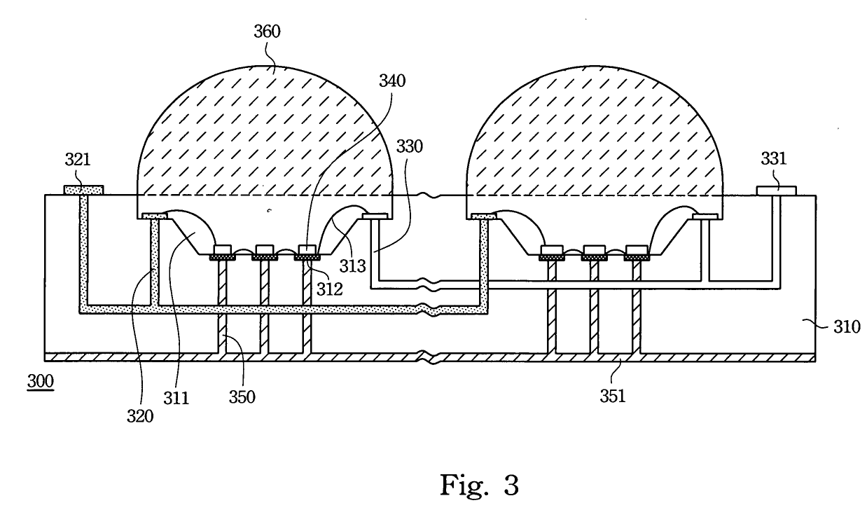

FIG. 3 is a cross-sectional diagram illustrating the high-power LED array according to the second preferred embodiment of the present invention. The high-power LED array 300 according to the second preferred embodiment of the present invention includes a PCB 310, anodes 320, cathodes 330, high-power LED dies 340, heat sinks 350, and lenses 360.

The PCB 310 includes cavities 311 arranged in an array. One or more high-power LED dies 340 are placed in the cavity 311. A plurality of one high-power LED dies 340 with the same emission wavelength, such as blue high-power LED dies, can be placed in the cavity 311. Alternatively, a combination of high-power LED dies 340 with different emission wavelengths can be employed. For example, a combination of red, green, and blue color high-power LED dies 340 in the cavity 311 result in a white, high-power LED array.

An anode 320 and a cathode 330 are inside the cavity 311, and are electrically connected to the high-power LED dies 340 for providing power to the high-power LED dies 340. The anode 320 and the cathode 330 of each cavity 311 are correspondingly connected to the anode 320 and the cathode 330 of the adjacent cavity 311 in parallel. The anode 320 and the cathode 330 are further connected to a common anode 321 and a common cathode 331, respectively.

The high-power LED dies 340 inside the cavity 311 are connected in parallel. As shown in the FIG. 3, the high-power LED dies 340 are placed on metal contacts 312 in the cavity 311. Metal contacts 312 are electrically connected via the wire 313, and the high-power LED dies 340 on both ends are further connected to the anode 320 and the cathode 330 in the cavity 311.

Further, the PCB 310 includes heat sinks 350. The heat sink 350 corresponds to each high-power LED die 340, and is located underneath the metal contact 312. The heat sink 350 is connected to the metal contact 312 for conducting the heat generated by the high-power LED dies 340. The heat sink 350 is further connected to a common heat sink 351. The common heat sink 351 is located on the backside of the PCB 310 for providing a larger dissipation area. By the common heat sink 351, the heat generated by the high-power LED dies 340 can be dissipated efficiently.

After the high-power LED dies 340 are placed in the cavity 311 and electrically connected to the anode 320 and the cathode 330 via the wire 313. The cavity 311 for securing the high-power LED dies 340 is filled with packing material. The packing material can be silicone or epoxy.

Subsequently, the lens 360 is placed on the cavity 311 and bonded to the packing material. The placement of each lens 360 can be adjusted for respective cavity 311 to optimize light emitted from each cavity 311.

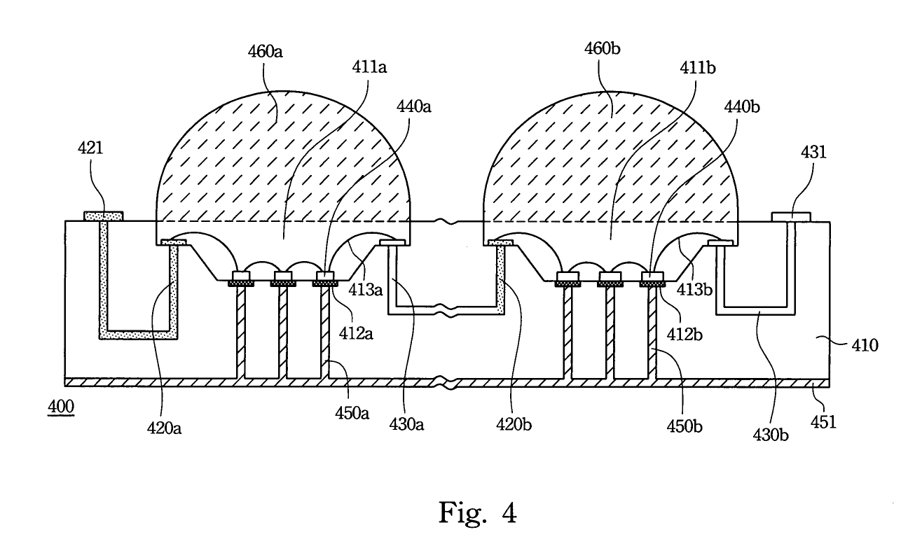

Further, the anodes and the cathodes of the adjacent cavities can also be electrically connected in series except for the parallel connection shown in the FIG. 2 and FIG. 3. FIG. 4 is a cross-sectional diagram illustrating a high-power LED array 400 according to the third preferred embodiment of the present invention. The PCB 410 includes a cavity 411a and a cavity 411b. High-power LED dies 440a and 440b are placed on the metal contacts 412a and 412b in the cavities 411a and 411b, respectively. The cavity 411a and 411b are electrically connected in series. The anode 420a is connected to a common anode 421, while the cathode 430b is connected to a common cathode 431. The adjacent cathode 430a and the anode 420b are connected in series. The high-power LED die 440a and 440b are connected in series via the wire 413a and 413b, respectively. The metal contact 412a and 412b are connected to the heat sink 450a and 450b, correspondingly. The heat sink 450a and 450b are further connected to a common heat sink 451 for conducting heat generated by the high-power LED die 440a and 440b. The lens 460a and 460b are placed on the cavity 411a and 411b for focusing the light emitted by the high-power LED die 440a and 440b, respectively.

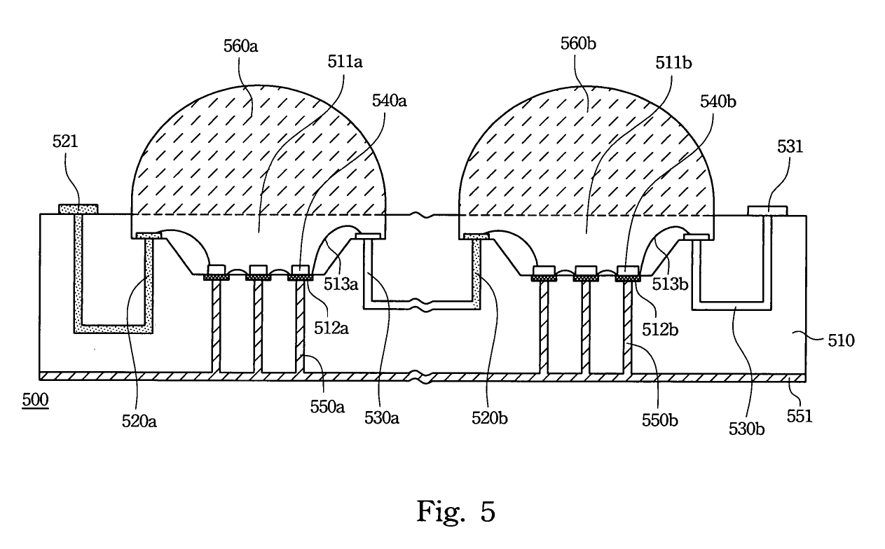

FIG. 5 is a cross-sectional diagram illustrating the high-power LED array 500 according to the fourth preferred embodiment of the present invention, where the cavities are electrically connected in series, and the high-power LED dies are electrically connected in parallel. The PCB 510 includes a cavity 511a and 511b. High-power LED dies 540a and 540b are placed on the metal contacts 512a and 512b in the cavities 511a and 511b, respectively. The cavities 511a and 511b are electrically connected in series. The anode 520a is connected to a common anode 521, while the cathode 530b is connected to a common cathode 531. The adjacent cathode 530a and the anode 520b are connected in series. The high-power LED dies 540a and 540b are connected in parallel via the wire 513a and 513b. The metal contacts 512a and 512b are connected to the heat sinks 550a and 550b, correspondingly. The heat sinks 550a and 550b are further connected to a common heat sink 551 for conducting heat generated by the high-power LED dies 540a and 540b. The lens 560a and 560b are placed on the cavity 511a and 511b for focusing the light emitted by the high-power LED dies 540a and 540b, respectively.

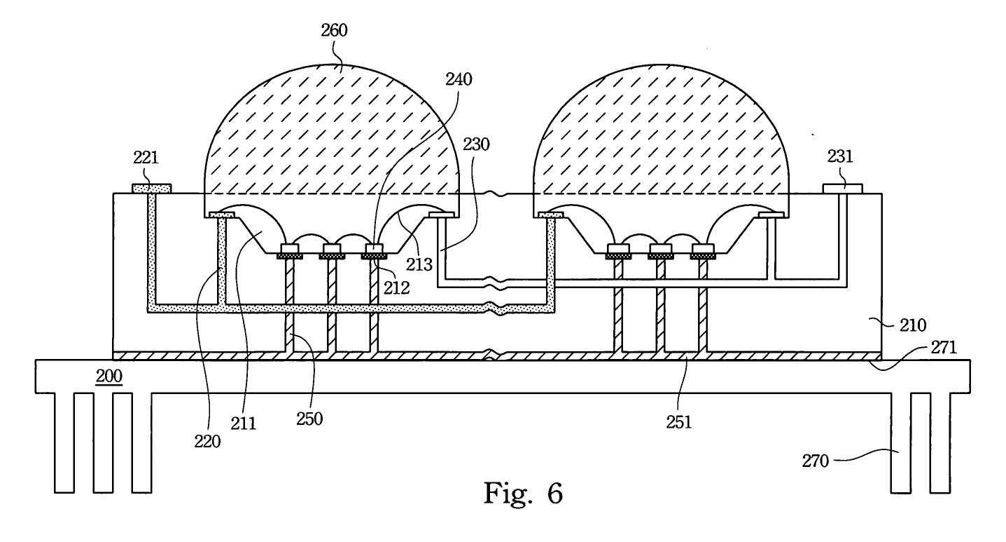

Further, the high-power LED array according to the present invention can be connected to a secondary heat sink for enhancing the heat dissipation efficiency. As shown in the FIG. 6, the high-power LED array 200 illustrated in the FIG. 2 is further connected to a secondary heat sink 270. The common heat sink 251 of the high-power LED array 200 is secured to the secondary heat sink 270 via a thermal conductive adhesive 271. The dissipation efficiency of the high-power LED array 200 can therefore be enhanced by the secondary heat sink 270.

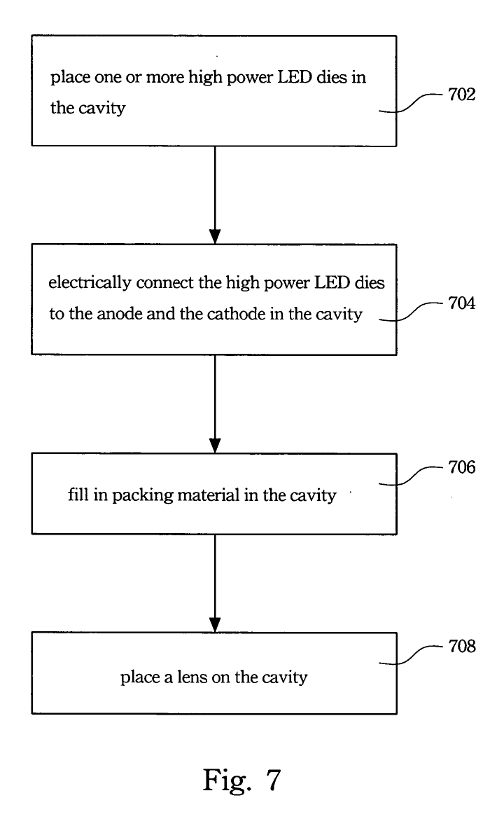

FIG. 7 is a flowchart illustrating the high-power LED array packing method for packing a high-power LED array on a PCB according to the present invention. The PCB includes cavities arranged in an array. An anode and a cathode are placed inside the cavity. The anodes of the cavities are electrically connected, while the cathodes of the cavities are also electrically connected. According to the high-power LED array packing method of the present invention, one or more high-power LED dies are placed in the cavity (step 702). The high-power LED dies can be III-V high-power LED dies, and can have the same or different emission wavelengths. Next, the high-power LED dies are electrically connected to the anode and the cathode in the cavity (step 704). The high-power LED dies can be connected in series or in parallel via wires. Subsequently, the cavity is filled with packing material for securing the high-power LED dies in the cavity (step 706). The packing material can be silicone or epoxy. Then, a lens is placed on the cavity for focusing light emitted by the high-power LED dies. The placement of the lens can be adjusted to optimize the light output.

The high-power LED array according to the present invention has a significantly reduced size, and the efficiency of heat dissipation and the optical alignment are also improved. The placement of the lens on the cavity can be adjusted to optimize the light output. Further, the configuration of more than one high-power LED dies in the cavity enables the combination of high-power LED dies with different emission wavelengths in a single high-power LED array. The light intensity per unit area of the high-power LED array is also dramatically increased. Further, the high-power LED array packing method according to the present invention simplifies the packing procedures, increases the power-to-volume ratio, and reduces the manufacturing cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A high-power LED array, the high-power LED array comprising:
a printed circuit board having a plurality of cavities;
a plurality of anodes electrically connecting to each other and located in the cavities;
a plurality of cathodes electrically connecting to each other and located in the cavities;
a plurality of high-power LED dies placed in the cavities and connecting to the anodes and the cathodes;
a packing material filling in the cavities for securing the high-power LED dies; and
a plurality of lenses placed on the cavities for focusing light emitted by the high-power LED dies.

2. The high-power LED array of claim 1, wherein the high-power LED dies are III-V high-power LED dies.

3. The high-power LED array of claim 1, further comprising at least one heat sink for conducting heat generated by the high-power LED dies.

4. The high-power LED array of claim 3, wherein the at least one heat sink is located underneath the high-power LED dies.

5. The high-power LED array of claim 3, wherein the at least one heat sink is connected to a secondary heat sink.

6. The high-power LED array of claim 1, wherein the cavities are arranged in an array.

7. The high-power LED array of claim 1, wherein the anodes are electrically connected in series.

8. The high-power LED array of claim 1, wherein the anodes are electrically connected in parallel.

9. The high-power LED array of claim 1, wherein the cathodes are electrically connected in series.

10. The high-power LED array of claim 1, wherein the cathodes are electrically connected in parallel.

11. The high-power LED array of claim 1, wherein the high-power LED dies are electrically connected to the anodes and the cathodes via wires.

12. The high-power LED array of claim 1, wherein the high-power LED dies are electrically connected to the anodes and the cathodes in series.

13. The high-power LED array of claim 1, wherein the high-power LED dies are electrically connected to the anodes and the cathodes in parallel.

14. The high-power LED array of claim 1, wherein the packing material is silicone.

15. The high-power LED array of claim 1, wherein the packing material is epoxy.

16. The high-power LED array of claim 1, wherein the lenses are adjusted to optimize light emitted by the high-power LED dies.

17. A high-power LED array packing method for packing a high-power LED array on a printed circuit board, the printed circuit board including a plurality of cavities, the cavities including anodes and cathodes, the anodes being electrically connected, and the cathodes being electrically connected, the high-power LED array packing method comprising:
placing at least one high-power LED die in the cavities;
electrically connecting the at least one high-power LED die to the anodes and the cathodes;
filling the cavities with packing materials for securing the at least one high-power LED die; and
placing lenses on the cavities.

18. The high-power LED array packing method of claim 17, wherein the at least one high-power LED die is III-V high-power LED die.

19. The high-power LED array packing method of claim 17, further comprising connecting at least one heat sink to the cavities for conducting heat generated by the at least one high-power LED die.

20. The high-power LED array packing method of claim 19, wherein the at least one heat sink is underneath the at least one high-power LED die.

21. The high-power LED array packing method of claim 19, wherein the at least one heat sink is connected to a secondary heat sink.

22. The high-power LED array packing method of claim 17, wherein the cavities are arranged in an array.

23. The high-power LED array packing method of claim 17, wherein the anodes are electrically connected in series.

24. The high-power LED array packing method of claim 17, wherein the anodes are electrically connected in parallel.

25. The high-power LED array packing method of claim 17, wherein the cathodes are electrically connected in series.

26. The high-power LED array packing method of claim 17, wherein the cathodes are electrically connected in parallel.

27. The high-power LED array packing method of claim 17, wherein the at least one high-power LED die is electrically connected to the anodes and the cathodes via wires.

28. The high-power LED array packing method of claim 17, wherein the at least one high-power LED die is electrically connected to the anodes and the cathodes in series.

29. The high-power LED array packing method of claim 17, wherein the at least one high-power LED die is electrically connected to the anodes and the cathodes in parallel.

30. The high-power LED array packing method of claim 17, wherein the packing material is silicone.

31. The high-power LED array packing method of claim 17, wherein the packing material is epoxy.

32. The high-power LED array packing method of claim 17, wherein the lenses can be adjusted to optimize light emitted by the at least one high-power LED die.
